(19) United States
(12) Patent Application Publication
(10) Pub. No.: US 2025/0359465 A1
(43) Pub. Date: Nov. 20, 2025

(54) DISPLAY DEVICE AND ELECTRONIC DEVICE INCLUDING THE SAME

(71) Applicant: Samsung Display Co., LTD., Yongin-si (KR)

(72) Inventors: SEUNGMIN LEE, Yongin-si (KR); SEONGGEUN WON, Yongin-si (KR)

(21) Appl. No.: 19/059,569

(22) Filed: Feb. 21, 2025

(30) Foreign Application Priority Data
May 17, 2024 (KR) 10-2024-0064567

(51) Int. Cl. H10K 59/80; H01L 25/075; H01L 25/16; H10H 20/812; H10H 29/85; H10H 29/852; H10K 59/127; H10K 102/00

(52) U.S. Cl. CPC H10K 59/8722; H10H 29/8506; H10H 29/852; H10K 59/127; H10K 59/873; H01L 25/0753; H01L 25/167; H10H 20/812; H10K 2102/351

(57) ABSTRACT

A display device includes a first substrate including a display area and a peripheral area, a circuit element layer and a light emitting element layer in the display area, a second substrate facing the light emitting element layer and defining a space therebetween, a sealant which in the peripheral area and bonding the first and second substrates to each other, a filler inside of the sealant and filling the space, and a dam which is in the peripheral area and between the light emitting element layer and the sealant. The dam includes a first side surface which faces the sealant and a second side surface which faces the light emitting element layer, and an angle between the first side surface and a lower surface of the dam which is greater than an angle between the second side surface and the lower surface of the dam.

This application claims priority to Korean Patent Application No. 10-2024-0064567, filed on May 17, 2024, and all the benefits accruing therefrom under 35 U.S.C. § 119, which is hereby incorporated by reference for all purposes as if fully set forth herein.

### BACKGROUND

### 1. Field

Embodiments relate to a display device and an electronic device including the display device.

### 2. Description of the Related Art

Flat panel display devices are replacing cathode ray tube display devices as display devices due to lightweight and thin characteristics of such flat panel display devices. As representative examples of such flat panel display devices, there are liquid crystal display devices and organic light emitting diode display devices. A display device may include a display substrate and an encapsulation substrate bonded to each other by a sealant.

### SUMMARY

Embodiments provide a display device with improved display quality and reliability.

Embodiments also provide an electronic device including the display device.

Additional features of the invention will be set forth in the description which follows, and in part will be apparent from the description, or may be learned by practice of the invention.

A display device according to an embodiment may include a first substrate including a display area and a peripheral area outside the display area, a circuit element layer disposed on the first substrate and including a plurality of insulating layers and a transistor, a light emitting element layer disposed in the display area on the circuit element layer and including a light emitting element electrically connected to the transistor, a second substrate disposed on the light emitting element layer and spaced apart from the light emitting element layer, a sealant disposed in the peripheral area between the first substrate and the second substrate and bonding the first substrate and the second substrate, a filler disposed in an inner side of the sealant and filling a space between the first substrate and the second substrate, and a first dam disposed in the peripheral area on the circuit element layer and located between the light emitting element layer and the sealant. An angle between a first side surface of the first dam facing the sealant and a lower surface of the first dam may be greater than an angle between a second side surface of the first dam facing the light emitting element layer and the lower surface of the first dam.

In an embodiment, in a plan view, the first dam may surround the light emitting element layer, and the sealant may surround the first dam.

In an embodiment, the display device may further include a first cover layer disposed on the first dam and protruding in a direction toward the sealant from the first side surface of the first dam.

In an embodiment, a first side surface of the first cover layer facing the sealant may be located in the direction toward the sealant from the first side surface of the first dam.

In an embodiment, a second side surface of the first cover layer facing the light emitting element layer may be located in a direction toward the light emitting element layer from the first side surface of the first dam, and may be located in the direction toward the sealant from the second side surface of the first dam.

In an embodiment, the first cover layer may cover a portion of an upper surface of the first dam closer to the sealant and may expose a remaining portion of the upper surface of the first dam closer to the light emitting element layer.

In an embodiment, a groove may be defined in an insulating layer disposed directly below the first dam among the insulating layers of the circuit element layer, and the groove may be adjacent to the first dam in the direction toward the sealant.

In an embodiment, in a plan view, the groove may surround the first dam.

In an embodiment, the display device may further include a second dam disposed in the peripheral area on the circuit element layer, located between the first dam and the sealant, and having a thickness greater than a thickness of the first dam.

In an embodiment, in a plan view, the first dam may surround the light emitting element layer, the second dam may surround the first dam, and the sealant may surround the second dam.

In an embodiment, an angle between a first side surface of the second dam facing the sealant and a lower surface of the second dam may be greater than an angle between a second side surface of the second dam facing the light emitting element layer and the lower surface of the second dam.

In an embodiment, the second dam may include a first layer disposed on the circuit element layer and having a thickness equal to the thickness of the first dam, and a second layer disposed on the first layer and having a first side surface facing the sealant and a second side surface facing the light emitting element layer.

In an embodiment, the display device may further include a second cover layer disposed on the second layer of the second dam and protruding in a direction toward the sealant from the first side surface of the second layer of the second dam.

In an embodiment, the second cover layer may cover an entire upper surface of the second layer of the second dam.

In an embodiment, a groove may be defined in the first layer of the second dam, and the groove may be adjacent to the second layer of the second dam in the direction toward the sealant.

A display device according to an embodiment may include a first substrate including a display area and a peripheral area outside the display area, a circuit element layer disposed on the first substrate and including a plurality of insulating layers and a transistor, a light emitting element layer disposed in the display area on the circuit element layer and including a light emitting element electrically connected to the transistor, a second substrate disposed on the light emitting element layer and spaced apart from the light emitting element layer, a sealant disposed in the peripheral area between the first substrate and the second substrate and bonding the first substrate and the second substrate, a filler disposed in an inner side of the sealant and filling a space between the first substrate and the second substrate, a first dam disposed in the peripheral area on the circuit element layer and located between the light emitting element layer and the sealant, and a first cover layer disposed on the first dam and protruding in only a direction toward the sealant from a side surface of the first dam.

In an embodiment, the first dam may have a first side surface facing the sealant and a second side surface facing the light emitting element layer. A first side surface of the first cover layer facing the sealant may be located in the direction toward the sealant from the first side surface of the first dam. A second side surface of the first cover layer facing the light emitting element layer may be located in a direction toward the light emitting element layer from the first side surface of the first dam, and may be located in the direction toward the sealant from the second side surface of the first dam.

In an embodiment, an angle between the first side surface of the first dam and a lower surface of the first dam may be greater than an angle between the second side surface of the first dam and the lower surface of the first dam.

In an embodiment, the display device may further include a second dam disposed in the peripheral area on the circuit element layer, located between the first dam and the sealant, and having a thickness greater than a thickness of the first dam, and a second cover layer disposed on the second dam and protruding in only the direction toward the sealant from a side surface of the second dam.

An electronic device according to an embodiment may include a display device configured to display an image, a memory device configured to store data for the display device, and a processor configured to perform computing functions for the display device. The display device may include a first substrate including a display area and a peripheral area which is outside the display area, a circuit element layer including an insulating layer and a transistor in the display area, on the first substrate, a light emitting element layer including a light emitting element which is in the display area and electrically connected to the transistor, on the circuit element layer, a second substrate facing the light emitting element layer and defining a space therebetween, a sealant which is in the peripheral area, between the first substrate and the second substrate, and bonds the first substrate and the second substrate to each other, a filler which is inside of the sealant and fills the space between the first substrate and the second substrate, and a dam which is in the peripheral area, on the circuit element layer, and between the light emitting element layer and the sealant in a direction along the first substrate. The dam may include a first side surface which faces the sealant and a second side surface which faces the light emitting element layer in the direction along the first substrate, and an angle between the first side surface and a lower surface of the dam which is greater than an angle between the second side surface and the lower surface of the dam.

The display device according to embodiments may include the first dam and the second dam disposed in the peripheral area and each having a structure in which an outer taper angle is greater than an inner taper angle. The first dam cover layer and the second dam cover layer each protruding in only an outward direction may respectively disposed on the first dam and the second dam. Accordingly, it is possible to effectively block air bubbles, which are generated in the peripheral area, from moving to the display area during the curing of the filler, without interrupting with a spreading of the filler applied on the display area toward the sealant before the curing of the filler as much as possible. Accordingly, a lifting of the common electrode and/or a capping layer due to the air bubbles may be prevented or reduced, while at the same time, a non-filling defect of the filler may be prevented or reduced. Accordingly, a display quality and a reliability of the display device may be improved.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the invention.

FIG. 1 is a plan view illustrating a display device according to an embodiment.

FIG. 2 is a cross-sectional view taken along line I-I′ of FIG. 1.

FIG. 3 is a plan view schematically illustrating a dam and a sealant of FIG. 2.

FIG. 4 is an enlarged cross-sectional view illustrating an example of an area A of FIG. 2.

FIG. 5 is an enlarged cross-sectional view illustrating an example of an area B of FIG. 4.

FIG. 6 is an enlarged cross-sectional view illustrating an example of an area A of FIG. 2.

FIGS. 7 to 18 are cross-sectional views illustrating a method of manufacturing a display device according to an embodiment.

FIG. 19 is a block diagram illustrating an electronic device according to an embodiment.

### DETAILED DESCRIPTION

Various example embodiments will be described more fully hereinafter with reference to the accompanying drawings, in which embodiments are shown. The present invention may, however, be embodied in many different forms and should not be construed as limited to the example embodiments set forth herein. Rather, these example embodiments are provided so that this disclosure will be thorough and complete, and will fully convey the scope of the present invention to those skilled in the art. In the drawings, the sizes and relative sizes of layers and regions may be exaggerated for clarity.

In the disclosure, various modifications can be made, various forms can be used, and specific embodiments will be illustrated in the drawings and described in detail in the text. However, this is not intended to limit the disclosure to a specific form disclosed, and it will be understood that all changes, equivalents, or substitutes which fall in the spirit and technical scope of the disclosure should be included.

It will be understood that, although the terms first, second, third etc. may be used herein to describe various elements, these elements should not be limited by these terms. These terms are used to distinguish one element from another. Thus, a first element discussed below could be termed a second element without departing from the teachings of the present invention.

As used herein, the term “and/or” includes any and all combinations of one or more of the associated listed items.

It will be understood that when an element is referred to as being related to another element such as being “connected” or “coupled” to another element, it can be directly connected or coupled to the other element or intervening element(s) may be present. In contrast, when an element is referred to as being related to another element such as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular example embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments will be described in detail with reference to the accompanying drawings. The same reference numerals are used for the same components in the drawings, and redundant descriptions of the same components will be omitted.

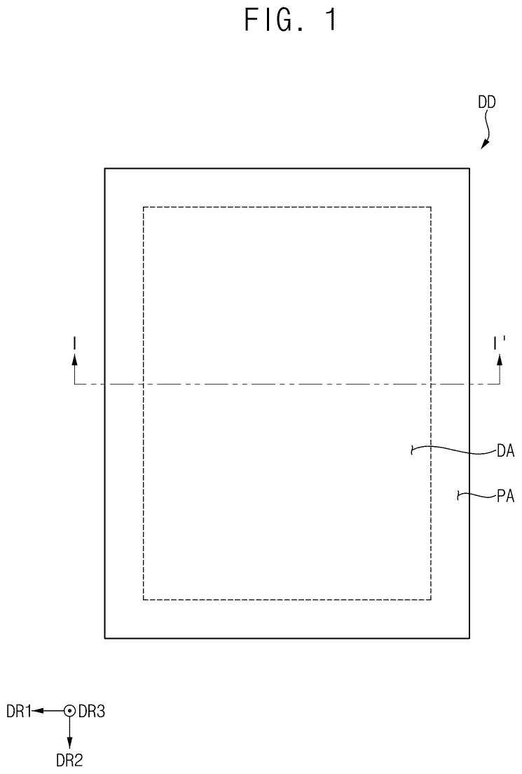

FIG. 1 is a plan view illustrating a display device DD according to an embodiment.

Referring to FIG. 1, a display device DD according to an embodiment may display an image in (or along) a third direction DR3, through a display surface in a plane defined by a first direction DR1 and a second direction DR2 which crosses the first direction DR1. For example, the second direction DR2 may be perpendicular to the first direction DR1. The third direction DR3 may be substantially parallel to a normal direction of the display surface. The display surface may correspond to an upper surface (or a front surface) of the display device DD. The display device DD and various components or layers thereof may have a thickness defined along the third direction DR3 (e.g., a thickness direction).

The display device DD may include a display area DA and a peripheral area PA. The image may be displayed in the display area DA. A plurality of pixels for generating the image may be disposed in the display area DA. For example, each of the pixels may emit one of red light, green light, and blue light.

Each of the pixels may include a pixel circuit and a light emitting element which is connected to the pixel circuit. The pixel circuit may include at least one thin film transistor and at least one capacitor. The thin film transistor may generate a driving current (e.g., electrical driving current) and provide the generated driving current to the light emitting element. The light emitting element may generate and/or emit light based on the driving current. For example, the light emitting element may include (or may be) an organic light emitting diode, an inorganic light emitting diode, a quantum dot light emitting diode, a micro light emitting diode, or the like. The image may be generated by combining light emitted from each of the pixels.

The peripheral area PA may be adjacent to the display area DA, such as being located around the display area DA. The peripheral area PA may be located outside the display area DA, that is, closer to the outer edge of the display device DD than the display area DA. For example, the peripheral area PA may surround the display area DA in a plan view, that is, be disposed extended along an entirety of the display area DA. A driver (e.g., a data driver, a gate driver, or the like) may be disposed in the peripheral area PA. The driver may provide various driving signals (e.g., electrical signals) for driving the pixels PX, such as a driving voltage, a gate signal, a data signal, or the like, to the display area DA.

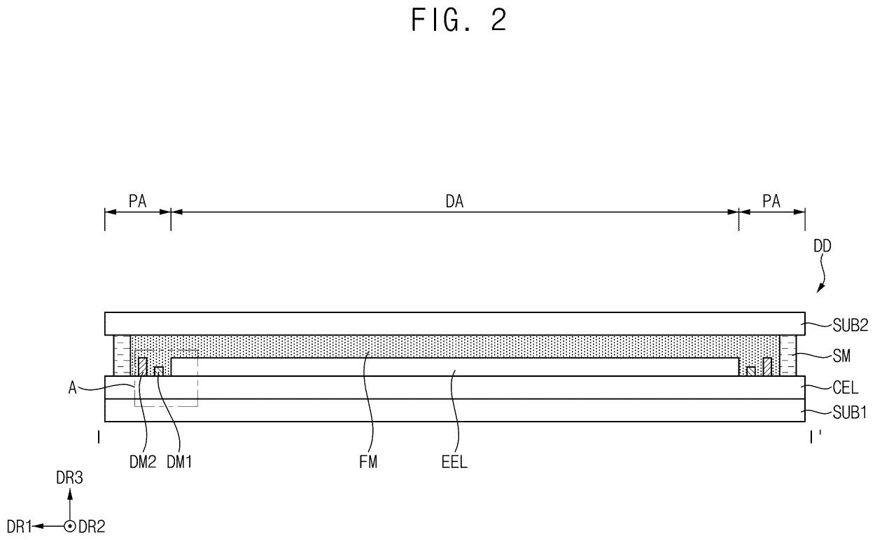

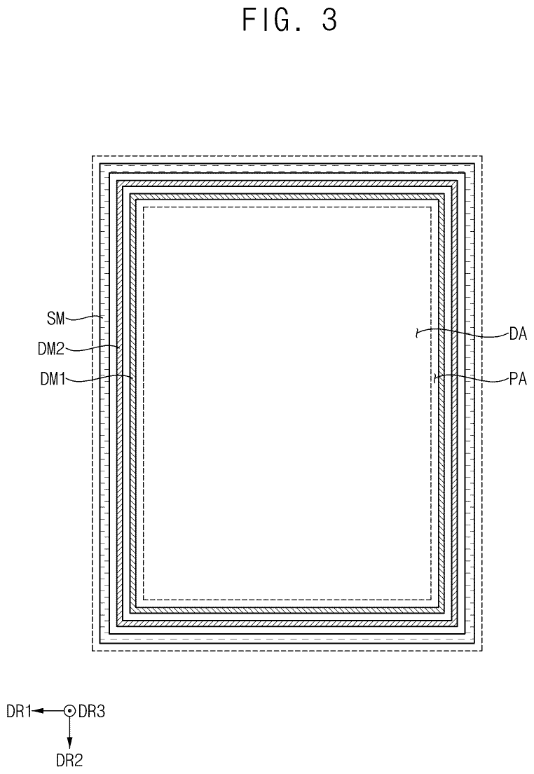

FIG. 2 is a cross-sectional view taken along line I-I′ of FIG. 1. FIG. 3 is a plan view schematically illustrating a dam and a sealant of FIG. 2.

Referring to FIGS. 2 and 3, in an embodiment, the display device DD may include a first substrate SUB1, a circuit element layer CEL, a light emitting element layer EEL, a first dam DM1, a second dam DM2, a second substrate SUB2, a sealant SM, and a filler FM.

The first substrate SUB1 may include the display area DA and the peripheral area PA which is adjacent to the display area DA. The first substrate SUB1 may be an insulating substrate formed of (or including) a transparent or opaque material. In an embodiment, the first substrate SUB1 may be a rigid substrate. For example, the first substrate SUB1 may include (or may be) a glass substrate, a metal substrate, a polymer substrate, or an organic/inorganic composite material substrate.

The circuit element layer CEL may be disposed on the first substrate SUB1. The circuit element layer CEL may include the thin film transistor, the capacitor, and a plurality of insulating layers constituting the pixel circuit. In an embodiment, at least one of the insulating layers may extend from the display area DA to the peripheral area PA, and may be entirely disposed on the display area DA and the peripheral area PA. The circuit element layer CEL may further include wires (e.g., signal wires) for transmitting various signals/voltages to the pixel circuit.

The light emitting element layer EEL may be disposed in the display area DA, on the circuit element layer CEL. The light emitting element layer EEL may include the light emitting element electrically connected to the thin film transistor.

A dam may be in the peripheral area PA, on the circuit element layer, CEL and between the light emitting element layer EEL and the sealant SM in a direction along the first substrate SUB1. Here, the dam includes a first side surface which faces the sealant SM and a second side surface which is opposite to the first side surface and faces the light emitting element layer in the direction along the first substrate SUB1. Within the dam, an inner angle between the first side surface and a lower surface of the dam is greater than an inner angle between the second side surface and the lower surface of the dam.

The first dam DM1 and the second dam DM2 may be disposed in the peripheral area PA on the first substrate SUB1. The first dam DM1 and the second dam DM2 may be disposed in the peripheral area PA, on the circuit element layer CEL. The first dam DM1 and the second dam DM2 may be disposed between the first substrate SUB1 and the second substrate SUB2 (or between the circuit element layer CEL and the second substrate SUB2). In an embodiment, the dam is provided in plural including a first dam DM1 and a second dam DM2 which is further from the display area DA than the first dam DM1. A thickness of the second dam DM2 is greater than a thickness of the first dam DM1.

In an embodiment, as illustrated in FIG. 3, in a plan view, the first dam DM1 may be spaced apart from the display area DA in an outward direction (e.g., a direction opposite to an inward direction, which is a direction toward a center of the display device DD in a plan view), and may surround the display area DA. In a plan view, the first dam DM1 may be spaced apart from the light emitting element layer EEL in the outward direction, and may surround the light emitting element layer EEL. In a plan view, the second dam DM2 may be spaced apart from the first dam DM1 in the outward direction, and may surround the first dam DM1 to be closer to an outer edge of the display device DD than the first dam DM1. As described later, the first dam DM1 and the second dam DM2 may prevent or reduce air bubbles which may be generated near the sealant SM during curing of the filler FM from moving to the display area DA.

Each of the dams may have a continuous shape, such as to form a closed-loop shape around the display area DA. The first dam DM1, the second dam DM2 and the sealant SM as a sealing pattern, may be in order in a direction from the display area DA to the outer edge of the display device DD. In an embodiment, the peripheral area PA may define a non-display area and may also define the outer edge of the display device DD.

Hereinafter, a structure in which the circuit element layer CEL, the light emitting element layer EEL, the first dam DM1, and the second dam DM2 are stacked on the first substrate SUB1 together with each other may be referred to as a display substrate or a stacked structure.

The second substrate SUB2 may be disposed on the display substrate. The second substrate SUB2) may be disposed on the light emitting element layer EEL to protect the light emitting element layer EEL. The second substrate SUB2 may be spaced apart from the light emitting element layer EEL. For example, the second substrate SUB2 may include (or may be) a glass substrate, a metal substrate, a polymer substrate, or an organic/inorganic composite material substrate. Hereinafter, the second substrate SUB2 may be referred to as an encapsulation substrate.

The sealant SM may be disposed in the peripheral area PA, between the display substrate and the encapsulation substrate. The sealant SM may be disposed in the peripheral area PA between the first substrate SUB1 and the second substrate SUB2 (or between the circuit element layer CEL and the second substrate SUB2). As illustrated in FIG. 3, in a plan view, the sealant SM may be spaced apart from the display area DA in the outward direction, and may surround the display area DA. In a plan view, the sealant SM may be spaced apart from the second dam DM2 in the outward direction, and may surround the second dam DM2.

The sealant SM may bond the display substrate and the encapsulation substrate to each other. The sealant SM may bond the first substrate SUB1 and the second substrate SUB2 (or the circuit element layer CEL and the second substrate SUB2) to each other. For example, the sealant SM may include a material such as a glass frit, a thermosetting resin, a photocurable resin, or the like, but embodiments are not limited thereto.

The first dam DM1 may be located between the light emitting element layer EEL and the sealant SM. The first dam DM1 may be located between the light emitting element layer EEL and the second dam DM2. That is, the first dam DM1 may be located in an outer side of the light emitting element layer EEL and in an inner side of the second dam DM2. The second dam DM2 may be located between the first dam DM1 and the sealant SM. That is, the second dam DM2 may be located in an outer side of the first dam DM1 and in an inner side of the sealant SM.

An inner space may be defined by the display substrate, the encapsulation substrate, and the sealant SM. Such inner space defined by these elements may constitute an empty space or an open space.

The filler FM may be filled in the inner space defined by the display substrate, the encapsulation substrate, and the sealant SM. The filler FM may be disposed in the inner side of the sealant SM, and may fill a space between the first substrate SUB1 and the second substrate SUB2 (or between the circuit element layer CEL and the second substrate SUB2). For example, the filler FM may include a thermosetting resin or a photocurable resin, but embodiments are not limited thereto. The filler FM may fill an entirety of the inner space.

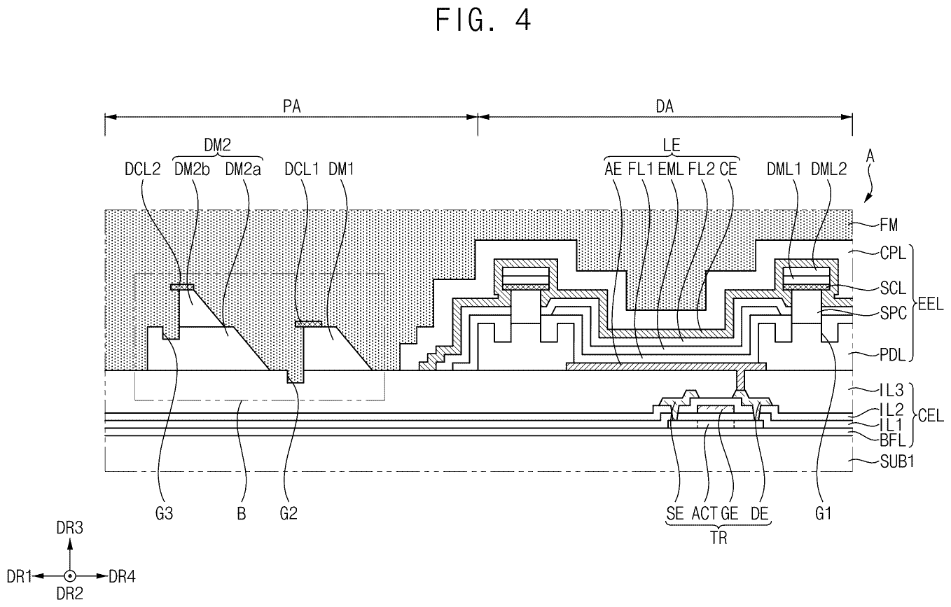

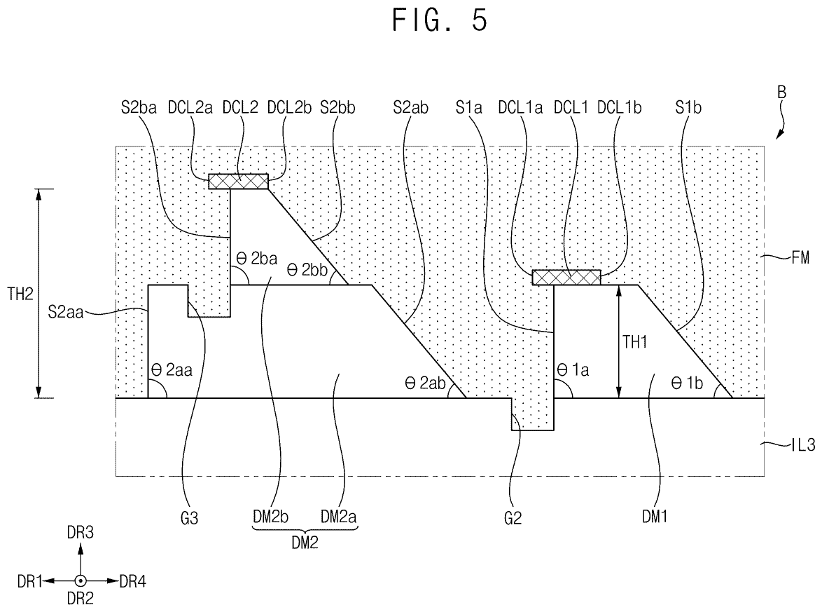

FIG. 4 is an enlarged cross-sectional view illustrating an example of an area A of FIG. 2. FIG. 5 is an enlarged cross-sectional view illustrating an example of an area B of FIG. 4. In FIGS. 4 and 5, the second substrate SUB2 may be omitted for convenience of illustration.

First, the pixel disposed in the display area DA of the display substrate will be described in more detail with reference to FIG. 4. The pixel may include a thin film transistor TR as a transistor (or a switching element) and the light emitting element LE which is electrically connected to the thin film transistor TR.

The circuit element layer CEL may be disposed on the first substrate SUB1. The circuit element layer CEL may include a buffer layer BFL, the thin film transistor TR, and first to third insulating layers IL1, IL2, and IL3. The thin film transistor TR may include an active layer ACT, a gate electrode GE, a source electrode SE, and a drain electrode DE.

The buffer layer BFL may be disposed on the first substrate SUB1. The buffer layer BFL may prevent or reduce impurities such as oxygen or moisture from penetrating into an upper portion of the first substrate SUB1 through the first substrate SUB1. The buffer layer BFL may include an inorganic insulating material such as a silicon compound, a metal oxide, or the like. For example, the buffer layer BFL may include silicon oxide (SiOₓ), silicon nitride (SiNₓ), silicon oxynitride (SiOₓN_{y}), silicon oxycarbide (SiOₓC_{y}), silicon carbonitride (SiCₓN_{y}), aluminum oxide (AlOₓ), aluminum nitride (AlNₓ), tantalum oxide (TaOₓ), hafnium oxide (HfOₓ), zirconium oxide (ZrOₓ), titanium oxide (TiOₓ), or the like. These may be used alone or in combination with each other. The buffer layer BFL may have a single-layer structure or a multi-layer structure including a plurality of insulating layers.

The active layer ACT may be disposed on the buffer layer BFL. The active layer ACT may include an oxide semiconductor, a silicon semiconductor, an organic semiconductor, or the like. For example, the oxide semiconductor may include at least one selected from oxides of indium (In), gallium (Ga), tin (Sn), zirconium (Zr), vanadium (V), hafnium (Hf), cadmium (Cd), germanium (Ge), chromium (Cr), titanium (Ti), and zinc (Zn). The silicon semiconductor may include an amorphous silicon, a polycrystalline silicon, or the like. The active layer ACT may include a source area, a drain area, and a channel area positioned between the source area and the drain area.

The first insulating layer IL1 may be disposed on the active layer ACT. The first insulating layer IL1 may cover the active layer ACT on the buffer layer BFL. The first insulating layer IL1 may include an inorganic insulating material. The first insulating layer IL1 may be referred to as a gate insulating layer.

The gate electrode GE may be disposed on the first insulating layer IL1. The gate electrode GE may overlap the channel area of the active layer ACT. The gate electrode GE may include a conductive material such as a metal, an alloy, a conductive metal nitride, a conductive metal oxide, a transparent conductive material, or the like. For example, the gate electrode GE may include gold (Au), silver (Ag), aluminum (Al), platinum (Pt), nickel (Ni), titanium (Ti), palladium (Pd), magnesium (Mg), calcium (Ca), lithium (Li), chromium (Cr), tantalum (Ta), tungsten (W), copper (Cu), molybdenum (Mo), scandium (Sc), neodymium (Nd), iridium (Ir), alloys containing aluminum, alloys containing silver, alloys containing copper, alloys containing molybdenum, aluminum nitride (AlNₓ), tungsten nitride (WNₓ), titanium nitride (TiNₓ), chromium nitride (CrNₓ), tantalum nitride (TaNₓ), strontium ruthenium oxide (SrRuOₓ), zinc oxide (ZnOₓ), indium tin oxide (ITO), tin oxide (SnOₓ), indium oxide (InOₓ), gallium oxide (GaOₓ), indium zinc oxide (IZO), or the like. These may be used alone or in combination with each other. The gate electrode GE may have a single-layer structure or a multi-layer structure including a plurality of conductive layers.

The second insulating layer IL2 may be disposed on the gate electrode GE. The second insulating layer IL2 may cover the gate electrode GE on the first insulating layer IL1. The second insulating layer IL2 may include an inorganic insulating material. The second insulating layer IL2 may be referred to as an interlayer insulating layer.

The source electrode SE and the drain electrode DE may be disposed on the second insulating layer IL2. The source electrode SE and the drain electrode DE may be connected to the source area and the drain area of the active layer ACT, respectively. Each of the source electrode SE and the drain electrode DE may include a conductive material.

The third insulating layer IL3 may be disposed on the source electrode SE and the drain electrode DE. The third insulating layer IL3 may include an organic insulating material. For example, the third insulating layer IL3 may include photoresist, polyacryl-based resin, polyimide-based resin, polyamide-based resin, siloxane-based resin, acryl-based resin, epoxy-based resin, or the like. These may be used alone or in combination with each other. The third insulating layer IL3 may be referred to as a via insulating layer.

FIG. 4 illustrates that the circuit element layer CEL includes four insulating layers, one semiconductor layer, and two conductive layers, but embodiments are not limited thereto. For example, the circuit element layer CEL may include five or more insulating layers, two or more semiconductor layers, and three or more conductive layers.

As described above, at least one of the insulating layers BFL, IL1, IL2, and IL3 included in the circuit element layer CEL may extend from the display area DA to the peripheral area PA. For example, the buffer layer BFL, the first insulating layer IL1, and the second insulating layer IL2 each including an inorganic insulating material may each extend to an edge (e.g., an outer edge) of the first substrate SUB1. That is, the buffer layer BFL, the first insulating layer IL1, and the second insulating layer IL2 may be entirely disposed on the first substrate SUB1. The third insulating layer IL3 including an organic insulating material may extend to only an inner side of an area where the sealant SM is disposed. That is, the sealant SM may be disposed on the second insulating layer IL2 to surround the third insulating layer IL3.

The light emitting element layer EEL may be disposed in the display area DA on the circuit element layer CEL. The light emitting element layer EEL may include the light emitting element LE, a pixel defining layer PDL, a spacer SPC, a spacer cover layer SCL, and a capping layer CPL. The light emitting element LE may include a pixel electrode AE, a first functional layer FL1, an emission layer EML, a second functional layer FL2, and a common electrode CE.

The pixel electrode AE may be disposed on the third insulating layer IL3. The pixel electrode AE may include a conductive material. The pixel electrode AE may have a single-layer structure or a multi-layer structure including a plurality of conductive layers. In an embodiment, the pixel electrode AE may be connected to the drain electrode DE through (or at) a contact hole defined or formed in the third insulating layer IL3. Accordingly, the pixel electrode AE may be electrically connected to the thin film transistor TR at a respective contact hole extended through a thickness of the third insulating layer IL3. In an embodiment, the pixel electrode AE may be electrically connected to a driving power voltage line, and the common electrode CE may be electrically connected to the drain electrode DE (e.g., to the transistor).

The pixel defining layer PDL may be disposed on the pixel electrode AE. The pixel defining layer PDL may cover a peripheral portion of the pixel electrode AE, and may define a pixel opening exposing a central portion of the pixel electrode AE to outside the pixel defining layer PDL. For example, the pixel defining layer PDL may have a grid shape defining a plurality of pixel openings in a plan view. The pixel defining layer PDL may include an organic insulating material. The pixel defining layer PDL may include solid (or material) portions and the pixel openings which are defined between such solid portions.

The spacer SPC may be disposed on the pixel defining layer PDL, such as on the solid portions thereof. In an embodiment, a plurality of spacers SPC may be disposed on the pixel defining layer PDL to be spaced apart from each other as island (or discrete) patterns. For example, the spacer SPC may serve to support structures which may be disposed on the display substrate during a process of manufacturing (or providing) the display device DD (e.g., a fine metal mask (“FMM”) for forming the emission layer EML or the like).

In an embodiment, the spacer SPC may be substantially simultaneously formed with the pixel defining layer PDL in a same process using a halftone mask. In an embodiment, the spacer SPC may be formed in a separate process, after the pixel defining layer PDL is formed.

The spacer cover layer SCL may be disposed on the spacer SPC. The spacer cover layer SCL may be disposed on an upper surface of the spacer SPC, and may protrude in the outward direction from a side surface of the spacer SPC. That is, the spacer cover SCL may extend in a lateral direction and further than the side surface of the spacer SPC. Here, the spacer cover layer SCL may have a tip structure which protrudes in the outward direction from the side surface of the spacer SPC. A size (or planar area) of a lower surface of the spacer cover layer SCL may be greater than a size (or planar area) of an upper surface of the spacer SPC. While FIG. 4 shows a lateral direction in a horizontal direction, it will be understood that the lateral direction may further extend along the second direction DR2. In an embodiment of providing the display substrate, the spacer cover layer SCL may serve to disconnect (or separate) a material layer each of the first functional layer FL1 and the second functional layer FL2. In an embodiment, the spacer cover layer SCL may include indium gallium zinc oxide (IGZO), but embodiments are not limited thereto.

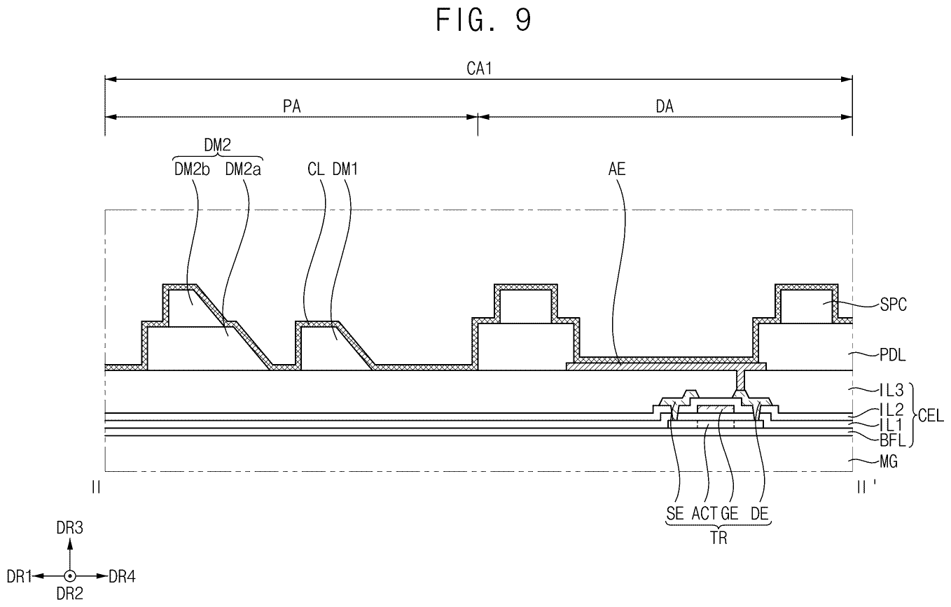

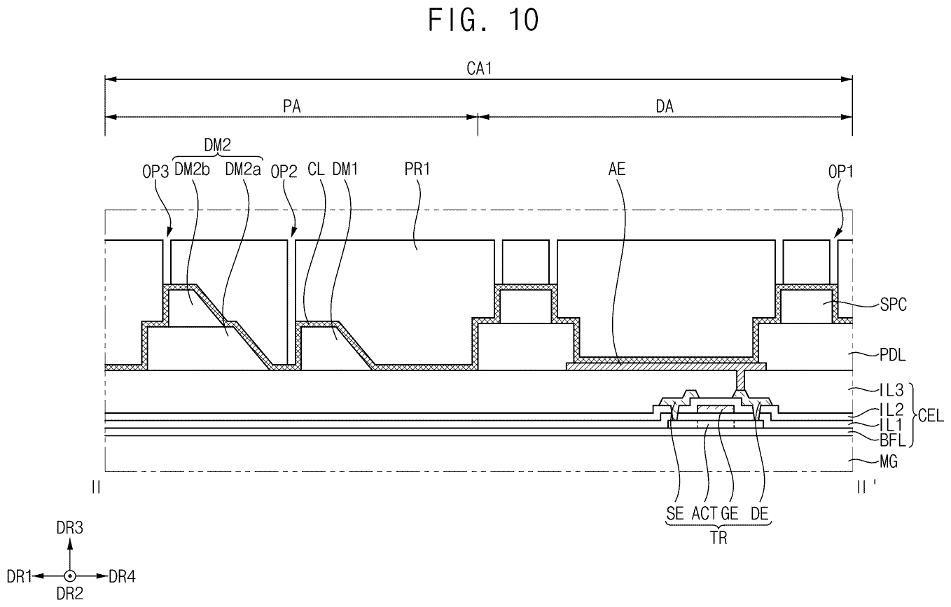

In an embodiment, a first groove G1 adjacent to the spacer SPC may be defined in (or by) the pixel defining layer PDL. For example, in a plan view, the first groove G1 may have a ring shape surrounding the spacer SPC having an island pattern shape. The first groove G1 may be formed in a process of forming the spacer cover layer SCL (see FIGS. 9 and 10). In an embodiment, a plurality of first grooves G1 respectively surrounding the plurality of spacers SPC may be defined in the pixel defining layer PDL.

The first functional layer FL1 may be disposed on the pixel electrode AE. The first functional layer FL1 may include a hole transport layer (HTL) and/or a hole injection layer (HIL). In an embodiment, the first functional layer FL1 may be entirely disposed on the display area DA.

The emission layer EML may be disposed on the first functional layer FL1. The emission layer EML may be disposed in the pixel opening of the pixel defining layer PDL. In some embodiments, the emission layer EML may include at least one of an organic light emitting material and quantum dot.

In an embodiment, the organic light emitting material may include a low molecular organic compound or a high molecular organic compound. Examples of the low molecular organic compound may include copper phthalocyanine, N,N′-diphenylbenzidine, tris-(8-hydroxyquinoline)aluminum, or the like. Examples of the high molecular organic compound may include poly(3,4-ethylenedioxythiophene), polyaniline, poly-phenylenevinylene, polyfluorene, or the like. These can be used alone or in a combination thereof.

In an embodiment, the quantum dot may include a core including a Group II-VI compound, a Group III-V compound, a Group IV-VI compound, a Group IV element, and/or a Group IV compound. In an embodiment, the quantum dot may have a core-shell structure including the core and a shell surrounding the core. The shell may serve as a protection layer for preventing the core from being chemically denatured to maintain semiconductor characteristics, and may serve as a charging layer for imparting electrophoretic characteristics to the quantum dot.

The second functional layer FL2 may be disposed on the emission layer EML. The second functional layer FL2 may include an electron transport layer (ETL) and/or an electron injection layer (EIL). In an embodiment, the second functional layer FL2 may be entirely disposed on the display area DA.

As illustrated in FIG. 4, a material layer of each of the first functional layer FL1 and the second functional layer FL2 may be disconnected (or separated) by the spacer cover layer SCL which has the tip structure extended further than the side surface of the spacer SPC. Accordingly, dark spot defects due to penetration of the filler FM through the first functional layer FL1 and/or the second functional layer FL2 may be prevented or reduced. In an embodiment, a first dummy layer DML1 and a second dummy layer DML2 may be disposed on the spacer cover layer SCL. The first dummy layer DML1 may include the same material as the first functional layer FL1 and may be substantially simultaneously formed with the first functional layer FL1. The second dummy layer DML2 may include the same material as the second functional layer FL2 and may be substantially simultaneously formed with the second functional layer FL2.

The common electrode CE may be disposed on the second functional layer FL2. The common electrode CE may include a conductive material. The common electrode CE may be entirely disposed on the display area DA. In an embodiment, the common electrode CE may be connected without being disconnected by the spacer cover layer SCL. In an embodiment, the common electrode CE may be disconnected by the spacer cover layer SCL. In this case as well, since each of the spacer SPC and the spacer cover layer SCL have an island pattern shape, the common electrodes CE of the light emitting elements LE may be electrically connected to each other.

The capping layer CPL may be disposed on the common electrode CE. The capping layer CPL may be entirely disposed on the display area DA, and may cover the entire common electrode CE. In an embodiment, the capping layer CPL may include an organic insulating material and/or an inorganic insulating material. In an embodiment, the capping layer CPL may extend to an inner side of the first dam DM1.

Next, the first dam DM1 and the second dam DM2 disposed in the peripheral area PA of the display substrate will be described in more detail with further reference to FIG. 5.

The first dam DM1 and the second dam DM2 may be disposed in the peripheral area PA, on the circuit element layer CEL. In an embodiment, as illustrated in FIGS. 4 and 5, the first dam DM1 and the second dam DM2 may be disposed on the third insulating layer IL3. In an embodiment, the third insulating layer IL3 may extend to only the inner side of the first dam DM1 in a direction from the display area DA, and the first dam DM1 and the second dam DM2 may be disposed on the second insulating layer IL2 which extends further than the inner side of the first dam DM1. Hereinafter, embodiments in which the first dam DM1 and the second dam DM2 are disposed on the third insulating layer IL3 will be described.

The first dam DM1 may be disposed in the outer side of the light emitting element layer EEL and in the inner side of the sealant SM. The first dam DM1 may have a lower surface, an upper surface, a first side surface Sla facing the sealant SM, and a second side surface S1b facing the light emitting element layer EEL. The first side surface S1a may be an outer side surface of the first dam DM1, and the second side surface S1b may be an inner side surface of the first dam DM1, such as considered relative to the display area DA.

In an embodiment, the first dam DM1 may have a structure in which an outer taper angle is greater than an inner taper angle. For example, an angle θ1 a between the first side surface S1a of the first dam DM1 and the lower surface of the first dam DM1 may be greater than an angle θ1b between the second side surface S1b of the first dam DM1 and the lower surface of the first dam DM1. For example, the angle θ1a as an inner angle between the first side surface S1a of the first dam DM1 and the lower surface of the first dam DM1 may be in a range of about 60 degrees to about 90 degrees, and the angle θ1b as an inner angle between the second side surface S1b of the first dam DM1 and the lower surface of the first dam DM1 may be in a range of about 30 degrees to about 60 degrees, but embodiments are not limited thereto.

Related to each dam, the display device DD may include a cover layer extended along an upper surface of the dam which is opposite to the lower surface of the dam. The cover layer protrudes further than the first side surface of the dam, in a direction toward the sealant SM (like in the first direction DR1). Here, the cover layer which protrudes further than the first side surface of the dam defines a cover first side surface which faces the sealant SM and is spaced apart from the first side surface in the direction toward the sealant SM and a cover second side surface which faces the light emitting element layer EEL and is spaced apart from the second side surface in the direction toward the sealant SM. Such a cover layer covers a portion of the upper surface of the dam which is adjacent to the sealant SM and exposes a remaining portion of the upper surface of the dam which is adjacent to the light emitting element layer EEL.

In an embodiment, the display device DD may further include a first dam cover layer DCL1 disposed on the first dam DM1. The first dam cover layer DCL1 may be disposed on the upper surface of the first dam DM1. For example, in a plan view, the first dam cover layer DCL1 may be spaced apart from the display area DA in the outward direction, and may surround the display area DA in the plan view.

In an embodiment, the first dam cover layer DCL1 may have a tip structure which protrudes in only one direction from the side surfaces of the first dam DM1. In an embodiment, the first dam cover layer DCL1 may protrude in only the outward direction toward the sealant SM (e.g., the first direction DR1 in FIGS. 4 and 5) from the side surfaces of the first dam DM1, and may not protrude in the inward direction toward the light emitting element layer EEL (e.g., a fourth direction DR4 in FIGS. 4 and 5).

The first dam cover layer DCL1 may protrude in the outward direction toward the sealant SM (e.g., the first direction DR1 in FIGS. 4 and 5) from the first side surface S1a of the first dam DM1.

The first dam cover layer DCL1 may have a first side surface DCL1a (e.g., a cover first side surface) facing the sealant SM and a second side surface DCL1b (e.g., a cover second side surface) facing the light emitting element layer EEL. The first side surface DCL1a may be an outer side surface of the first dam cover layer DCL1, and the second side surface DCL1b may be an inner side surface of the first dam cover layer DCL1.

The first side surface DCL1a of the first dam cover layer DCL1 may be located in the outward direction toward the sealant SM (e.g., the first direction DR1 in FIGS. 4 and 5) from the first side surface S1a of the first dam DM1. The second side surface DCL1b of the first dam cover layer DCL1 may be located between the first side surface S1a of the first dam DM1 and the second side surface S1b of the first dam DM1 in a direction along the upper surface thereof. That is, the second side surface DCL1b of the first dam cover layer DCL1 may be located in the inward direction toward the light emitting element layer EEL (e.g., the fourth direction DR4 in FIGS. 4 and 5) from the first side surface S1a of the first dam DM1, and may be located in the outward direction toward the sealant SM (e.g., the first direction DR1 in FIGS. 4 and 5) from the second side surface S1b of the first dam DM1.

In an embodiment, as illustrated in FIG. 5, the first dam cover layer DCL1 may cover an outer portion of the upper surface of the first dam DM1 (e.g., a portion closer to the sealant SM) and may expose an inner portion of the upper surface of the first dam DM1 (e.g., a remaining portion closer to the light emitting element layer EEL) to outside the dam cover. In an embodiment, the first dam cover layer DCL1 may cover the entire upper surface of the first dam DM1.

In an embodiment, the first dam cover layer DCL1 may include the same material as the spacer cover layer SCL and may be substantially simultaneously formed with the spacer cover layer SCL. For example, the first dam cover layer DCL1 may include IGZO or the like, but embodiments are not limited thereto.

In an embodiment, a second groove G2 adjacent to the first dam DM1 may be defined in an insulating layer (e.g., the third insulating layer IL3) disposed directly below the first dam DM1 among the insulating layers BFL, IL1, IL2, and IL3 of the circuit element layer CEL. The insulating layers BFL, IL1, IL2, and IL3 may be collectively referred to as an insulating layer. The second groove G2 may be adjacent to the first dam DM1 in the outward direction toward the sealant SM (e.g., the first direction DR1 in FIGS. 4 and 5). For example, in a plan view, the second groove G2 may have a ring shape surrounding the first dam DM1. The second groove G2 may be formed in a process of forming the first dam cover layer DCL1 (see FIGS. 9 and 10).

The second dam DM2 may be disposed in the outer side of the first dam DM1 and in the inner side of the sealant SM. In an embodiment, a thickness TH2 of the second dam DM2 may be greater than a thickness TH1 of the first dam DM1. For example, the thickness TH1 of the first dam DM1 may be defined as a maximum distance between the lower surface of the first dam DM1 and the upper surface of the first dam DM1, and the thickness TH2 of the second dam DM2 may be defined as a maximum distance between a lower surface of the second dam DM2 and an upper surface of the second dam DM2.

In an embodiment, the second dam DM2 may include a first layer DM2a disposed on the circuit element layer CEL and a second layer DM2b disposed on the first layer DM2a. In an embodiment, the first dam DM1 and the first layer DM2a of the second dam DM2 may be substantially simultaneously formed with the pixel defining layer PDL, and the second layer DM2b of the second dam DM2 may be substantially simultaneously formed with the spacer SPC. However, this is an example, and embodiments are not limited thereto. Here, the pixel defining layer PDL, the first dam DM1 and the first layer DM2a of the second dam DM2 may be in a same layer as each other.

The first layer DM2a of the second dam DM2 may have a lower surface, an upper surface, a first side surface S2aa facing the sealant SM, and a second side surface S2ab facing the light emitting element layer EEL. The first side surface S2aa may be an outer side surface of the first layer DM2a, and the second side surface S2ab may be an inner side surface of the first layer DM2a.

The second layer DM2b of the second dam DM2 may have a lower surface, an upper surface, a first side surface S2ba facing the sealant SM, and a second side surface S2bb facing the light emitting element layer EEL. The first side surface S2ba may be an outer side surface of the second layer DM2b, and the second side surface S2bb may be an inner side surface of the second layer DM2b.

Each of the first side surface S2aa of the first layer DM2a and the first side surface S2ba of the second layer DM2b may face an inner side surface of the sealant SM. Each of the second side surface S2ab of the first layer DM2a and the second side surface S2bb of the second layer DM2b may face the first side surface S1a of the first dam DM1.

In an embodiment, the first layer DM2a is on the circuit element layer and has a thickness equal to the thickness of the first dam DM1. Each of the first layer DM2a and the second layer DM2b within the second dam DM2 has a first side sub-surface (e.g., the first side surface S2aa) which faces the sealant SM and corresponds to the first side surface of the second dam DM2, and a second side sub-surface (e.g., the second side surface S2bb) which faces the light emitting element layer EEL and corresponds to the second side surface of the second dam DM2. Here, within each of the first layer and the second layer of the second dam DM2, an angle between the first side sub-surface and a lower surface of the second dam DM2 is greater than an angle between the second side sub-surface and the lower surface of the second dam DM2.

In an embodiment, the second dam DM2 may have a structure in which an outer taper angle is greater than an inner taper angle. For example, an angle θ2aa as an inner angle between the first side surface S2aa of the first layer DM2a and the lower surface of the first layer DM2a may be greater than an angle θ2ab as an inner angle between the second side surface S2ab of the first layer DM2a and the lower surface of the first layer DM2a. For example, an angle θ2ba as an inner angle between the first side surface S2ba of the second layer DM2b and the lower surface of the second layer DM2b may be greater than an angle θ2bb as an inner angle between the second side surface S2bb of the second layer DM2b and the lower surface of the second layer DM2b. For example, each of the angle θ2aa between the first side surface S2aa of the first layer DM2a and the lower surface of the first layer DM2a and the angle θ2ba between the first side surface S2ba of the second layer DM2b and the lower surface of the second layer DM2b may be in a range of about 60 degrees to about 90 degrees, and each of the angle θ2ab between the second side surface S2ab of the first layer DM2a and the lower surface of the first layer DM2a and the angle θ2bb between the second side surface S2bb of the second layer DM2b and the lower surface of the second layer DM2b may be in a range of about 30 degrees to about 60 degrees, but embodiments are not limited thereto.

In an embodiment, the display device DD may further include a second dam cover layer DCL2 disposed on the second dam DM2. The second dam cover layer DCL2 may be disposed on the upper surface of the second layer DM2b of the second dam DM2. For example, in a plan view, the second dam cover layer DCL2 may be spaced apart from the first dam cover layer DCL1 in the outward direction, and may surround the first dam cover layer DCL1. Here, the upper surface of the second dam DM2 is defined by the second layer DM2b, and the second cover layer (e.g., the second dam cover layer DCL2) covers an entirety of the upper surface of the second dam DM2 which is defined by the second layer DM2b.

In an embodiment, the second dam cover layer DCL2 may have a tip structure which protrudes in only one direction from the side surfaces of the second layer DM2b of the second dam DM2. In an embodiment, the second dam cover layer DCL2 may protrude in only the outward direction toward the sealant SM (e.g., the first direction DR1 in FIGS. 4 and 5) from the side surfaces of the second layer DM2b of the second dam DM2, and may not protrude in the inward direction toward the light emitting element layer EEL (e.g., the fourth direction DR4 in FIGS. 4 and 5).

The second dam cover layer DCL2 may protrude in the outward direction toward the sealant SM (e.g., the first direction DR1 in FIGS. 4 and 5) from the first side surface S2ba of the second layer DM2b of the second dam DM2.

The second dam cover layer DCL2 may have a first side surface DCL2a facing the sealant SM and a second side surface DCL2b facing the light emitting element layer EEL. The first side surface DCL2a may be an outer side surface of the second dam cover layer DCL2, and the second side surface DCL2b may be an inner side surface of the second dam cover layer DCL2.

The first side surface DCL2a of the second dam cover layer DCL2 may be located in the outward direction toward the sealant SM (e.g., the first direction DR1 in FIGS. 4 and 5) from the first side surface S2ba of the second layer DM2b. The second side surface DCL2b of the second dam cover layer DCL2 may be located between the first side surface S2ba of the second layer DM2b and the second side surface S2bb of the second layer DM2b. That is, the second side surface DCL2b of the second dam cover layer DCL2 may be located in the inward direction toward the light emitting element layer EEL (e.g., the fourth direction DR4 in FIGS. 4 and 5) from the first side surface S2ba of the second layer DM2b, and may be located in the outward direction toward the sealant SM (e.g., the first direction DR1 in FIGS. 4 and 5) from the second side surface S2bb of the second layer DM2b.

In an embodiment, as illustrated in FIG. 5, the second dam cover layer DCL2 may cover the entire upper surface of the second layer DM2b. In an embodiment, the second dam cover layer DCL2 may cover an outer portion of the upper surface of the second layer DM2b (e.g., a portion closer to the sealant SM) and may expose an inner portion of the upper surface of the second dam DM2 (e.g., a remaining portion closer to the light emitting element layer EEL).

In an embodiment, the second dam cover layer DCL2 may include the same material as the spacer cover layer SCL and the first dam cover layer DCL1, and may be substantially simultaneously formed with the spacer cover layer SCL and the first dam cover layer DCL1. For example, the second dam cover layer DCL2 may include IGZO or the like, but embodiments are not limited thereto. That is, spacer cover layer SCL, the first dam cover layer DCL1 and the second dam cover layer DCL2 may be in a same layer as each other.

In an embodiment, as illustrated in FIGS. 4 and 5, the second layer DM2b may be disposed on an inner portion of the first layer DM2a, and may not be disposed on an outer portion of the first layer DM2a. That is, the second layer DM2b may expose an outer portion of the upper surface of the first layer DM2a (e.g., a portion closer to the sealant SM) to outside the second layer DM2b.

In an embodiment, a third groove G3 adjacent to the second layer DM2b may be defined in the outer portion of the first layer DM2a which is not covered by the second layer DM2b. The third groove G3 may be adjacent to the second layer DM2b in the outward direction toward the sealant SM (e.g., the first direction DR1 in FIGS. 4 and 5). For example, in a plan view, the third groove G3 may have a ring shape surrounding the second layer DM2b. The third groove G3 may be formed in a process of forming the second dam cover layer DCL2 (see FIGS. 9 and 10).

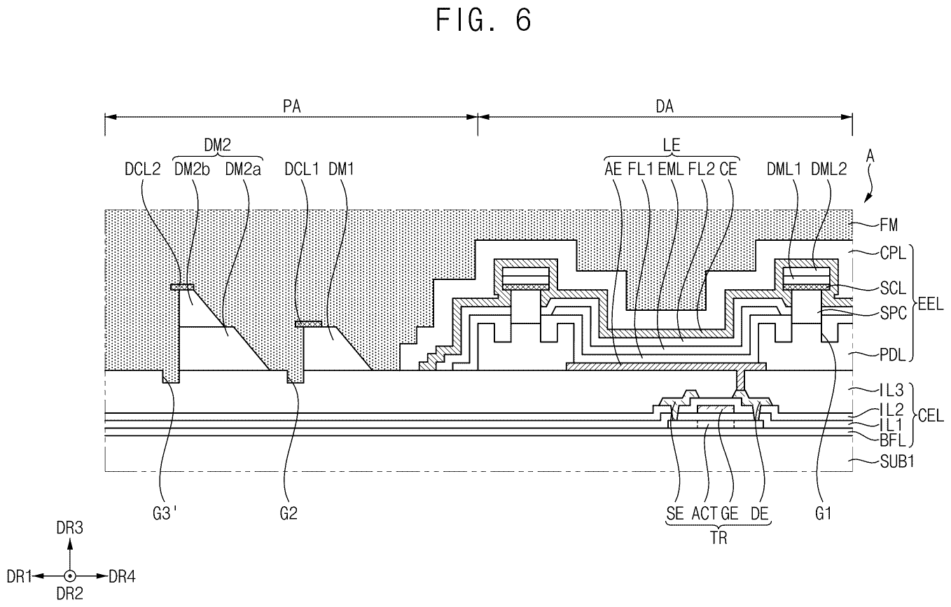

FIG. 6 is an enlarged cross-sectional view illustrating an example of an area A of FIG. 2.

In an embodiment, as illustrated in FIG. 6, the outer side surface of the first layer DM2a and the outer side surface of the second layer DM2b may be aligned with each other, that is, disposed in a same plane extended along the thickness direction. In this case, a third groove G3′ adjacent to the first layer DM2a may be defined in the third insulating layer IL3. The third groove G3′ may be adjacent to the first layer DM2a in the outward direction toward the sealant SM (e.g., the first direction DR1 in FIG. 6). For example, in a plan view, the third groove G3′ may have a ring shape surrounding the first layer DM2a.

During the manufacturing process of the display device DD, an upper portion of the dam may be stamped or compressed by the structures (e.g., FMM or the like) which may be disposed on the display substrate. When the filler FM is cured after the first substrate SUB1 and the second substrate SUB2 are bonded to each other, air bubbles (e.g., linear air bubbles) may be generated due to shrinkage of the filler FM. In particular, the air bubbles may be generated closer to the sealant SM or near a portion of the dam whose upper portion is stamped. If the bubbles move to the display area DA, they may cause a lifting of the common electrode CE and/or the capping layer CPL so that the dark spot defects may occur. Therefore, a display quality of the display device DD may be decreased.

According to embodiments, among the dams DM1 and DM2 outside the display area DA, the second dam DM2 closer to the sealant SM may have the thickness TH2 less than the thickness TH1 of the first dam DM1 closer to the display area DA. Accordingly, during the manufacturing process of the display device DD, the first dam DM1 closer to the display area DA may be prevented or reduced from being stamped by the FMM or the like. In other words, generation of the air bubbles in an area closer to the display area DA may be minimized.

In addition, together with the second dam DM2 closer to the sealant SM having the thickness TH2 less than the thickness TH1 of the first dam DM1 closer to the display area DA, each of the first dam DM1 and the second dam DM2 may have a structure in which an outer taper angle is greater than an inner taper angle, and the first dam cover layer DCL1 and the second dam cover layer DCL2 which protrude further than an underlying side surface in only the outward direction toward the sealant SM may be respectively disposed on the first dam DM1 and the second dam DM2. Accordingly, it is possible to effectively block the air bubbles, which are generated near the sealant SM or near the second dam DM2, from moving to the display area DA (e.g., in the inward direction) during the curing of the filler FM, without interrupting with a spreading of the filler FM applied on the display area DA toward the sealant SM (e.g., in the outward direction) before the curing of the filler FM as much as possible. Accordingly, the lifting of the common electrode CE and/or the capping layer CPL due to the air bubbles may be prevented or reduced, while at the same time, a non-filling defect of the filler FM may be prevented or reduced. Accordingly, the display quality and a reliability of the display device DD may be improved.

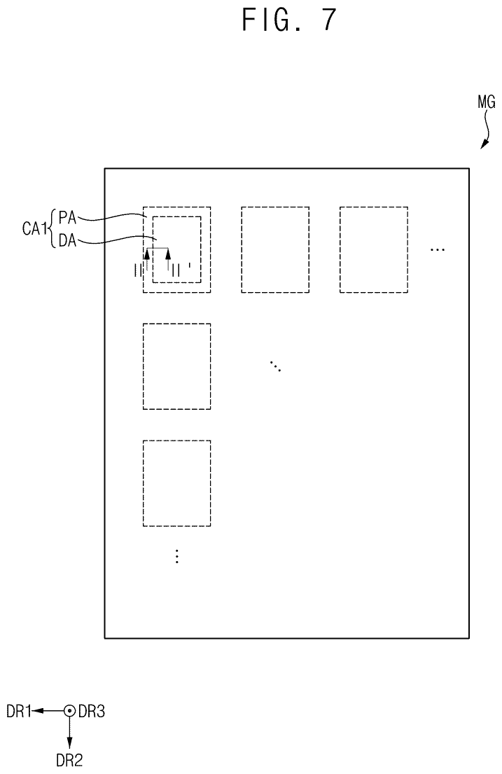

FIGS. 7 to 18 are cross-sectional views illustrating processes in a method of manufacturing (or providing) a display device DD according to an embodiment.

Hereinafter, an example of a method of manufacturing the display device DD of FIGS. 1 to 5 will be described with reference to FIGS. 7 to 18. Hereinafter, repeated descriptions may be omitted or simplified.

Referring to FIG. 7, a mother substrate MG including the same material as the first substrate SUB1 may be prepared. The mother substrate MG may be an intermediate substrate on which a plurality of cell areas are defined in order to obtain a plurality of display devices DD at once. Each of the cell areas may correspond to one display device DD, and may include the display area DA and the peripheral area PA. The cell area defined on the mother substrate MG will be referred to as a first cell area CA1. A portion of the mother substrate MG corresponding to the first cell area CA1 may become the first substrate SUB1 through a cutting process described later. The outer dotted line in FIG. 7 may represent an outer edge of the first substrate SUB1 of a respective display device DD which is provided from the mother substrate MG having various layers thereon. The display device DD may be a separated portion of the intermediate substrate (e.g., the mother substrate MG).

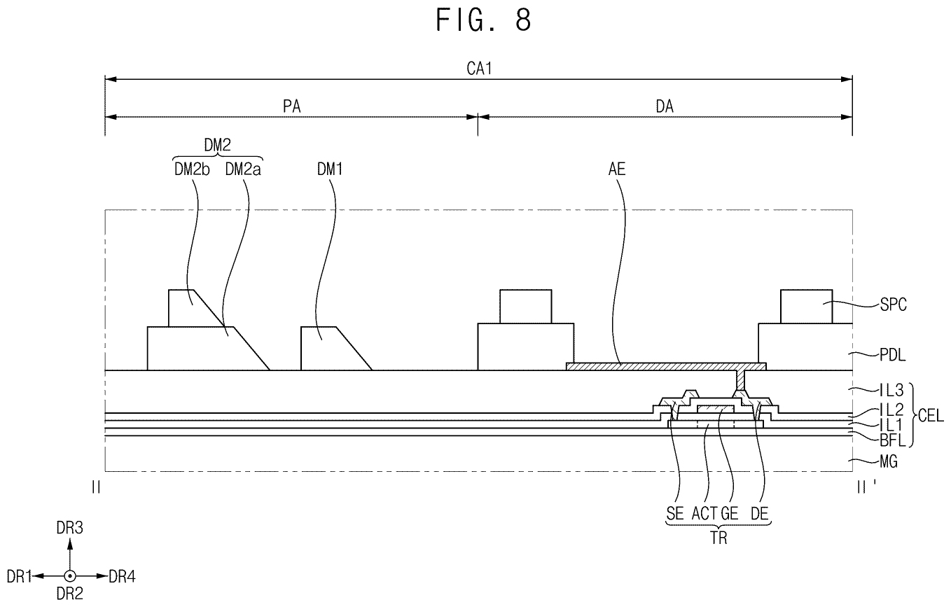

Each of FIGS. 8 to 15 is cross-sectional view taken along line II-II′ of FIG. 7. For example, each of FIGS. 8 to 15 may correspond to FIG. 4.

Referring to FIGS. 8 to 15, the circuit element layer CEL, the light emitting element layer EEL, the first dam DM1, the second dam DM2, the first dam cover layer DCL1, and the second dam cover layer DCL2 may be formed (or provided) on each of the first cell areas CA1, such as on one surface of the mother substrate MG. Such surface may be a major surface of the mother substrate MG, like an upper surface extended along the plane defined by the first direction DR1 and the second direction DR2 crossing each other.

First, referring to FIG. 8, the circuit element layer CEL including the thin film transistor TR may be formed on the mother substrate MG. The pixel electrode AE may be formed in the display area DA, on the circuit element layer CEL. Next, the pixel defining layer PDL and the spacer SPC may be formed in the display area DA on the circuit element layer CEL, and the first dam DM1 and the second dam DM2 may be formed in the peripheral area PA on the circuit element layer CEL. The first dam DM1 may be formed in the peripheral area PA to surround the pixel defining layer PDL in a plan view. The second dam DM2 may be formed in the peripheral area PA to surround the first dam DM1 in a plan view.

In an embodiment, the method includes providing cell areas (e.g., first cell areas CA1) respectively corresponding to the display device DD, on a mother substrate MG, each of the cell areas including a display area DA of the display device DD, a peripheral area PA of the display device DD which is outside the display area DA, a circuit element layer CEL including an insulating layer and a transistor TR, in the display area DA, and a pixel electrode AE of a light emitting element LE which is electrically connected to the transistor TR, in the display area DA.

A preliminary pixel defining layer may include each of the patterns PDL, DM1 and DM2a shown in FIG. 8. A preliminary spacer layer may include each of the patterns SPC and DM2b shown in FIG. 8. A preliminary organic insulating layer from which both the pixel defining layer PDL and the dams are provided, may include all of these patterns together. That is, the various patterns within the respective layers are in a same layer as each other. As being in a same layer, elements may be formed in a same process and/or include a same material as each other, elements may be respective portions of a same material layer, elements may be on a same layer by forming an interface with a same underlying or overlying layer, elements may be coplanar with each other or be disposed in a same thickness, etc., without being limited thereto.

In an embodiment, the pixel defining layer PDL, the spacer SPC, the first dam DM1, and the second dam DM2 may be substantially simultaneously formed with each other, from a same material layer. For example, an organic insulating layer including a photoresist may be formed on the circuit element layer CEL and the pixel electrode AE. Then, the organic insulating layer may be patterned by exposing process using a halftone mask and developing process so that each of the pixel defining layer PDL, the spacer SPC, the first dam DM1, and the second dam DM2 may be substantially simultaneously formed with each other from the same organic insulating layer. In an embodiment, in the each cell area (e.g., the first cell area CA1), the method includes, providing a pixel defining layer PDL on the pixel electrode AE in the display area, together with providing (e.g., simultaneously formed with) a dam surrounding the pixel defining layer PDL in the peripheral area PA.

In an embodiment, each of the first dam DM1 and the second dam DM2 may be formed to have a structure in which the outer taper angle of various thickness portions thereof is greater than the inner taper angle. For example, the first dam DM1 and the second dam DM2 may be formed as the structure illustrated in FIG. 8 through an asymmetric design of the halftone mask.

Referring to FIG. 9, a cover layer CL may be formed on the pixel electrode AE, the pixel defining layer PDL, the spacer SPC, the first dam DM1, and the second dam DM2. A material layer for providing the cover layer CL may be formed on the entire display area DA and the peripheral area PA. For example, the cover layer CL may be formed by sputtering IGZO or the like.

Referring to FIG. 10, a first photoresist layer PR1 may be formed on the cover layer CL. The first photoresist layer PR1 may be patterned to have a first opening OP1 adjacent to the spacer SPC, a second opening OP2 adjacent to the first dam DM1, and a third opening OP3 adjacent to the second dam DM2. As being adjacent, elements may not overlap each other, such as to be adjacent or spaced apart from each other in a planar direction, like along the mother substrate MG.

In an embodiment, in a plan view, the first opening OP1 may have a ring shape surrounding the spacer SPC having an island pattern shape. In an embodiment, the first photoresist layer PR1 may have a plurality of first openings OP1 respectively surrounding the plurality of spacers SPC.

The second opening OP2 may be adjacent to the first dam DM1 in the outward direction (e.g., the first direction DR1 in FIG. 10). In a plan view, the second opening OP2 may have a ring shape surrounding the first dam DM1.

The third opening OP3 may be adjacent to the second dam DM2 in the outward direction (e.g., the first direction DR1 in FIG. 10). In a plan view, the third opening OP3 may have a ring shape surrounding the second dam DM2.

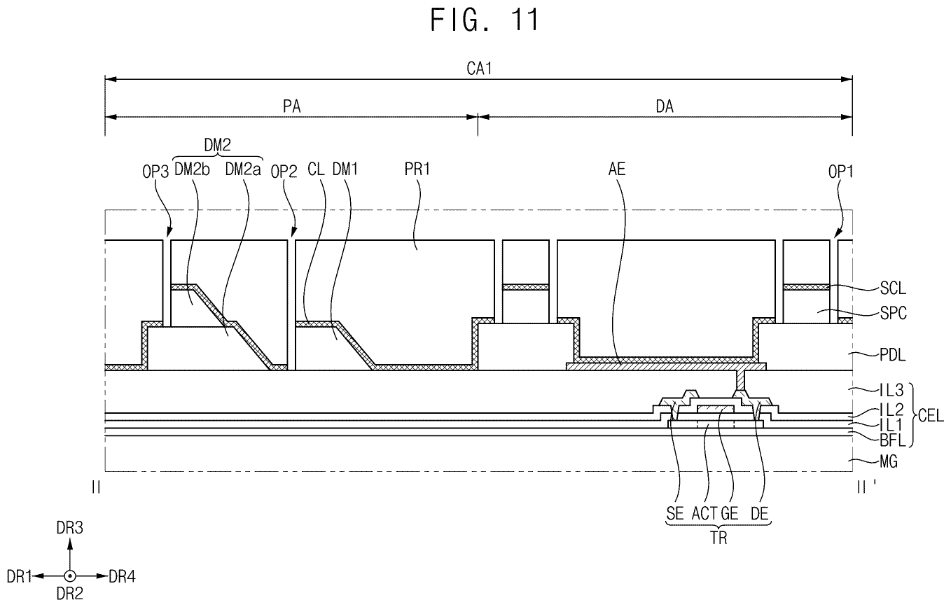

Referring to FIG. 11, the material layer of the cover layer CL as a preliminary cover layer may be patterned using the first photoresist layer PR1 as an etching mask. For example, the cover layer CL may be patterned by isotropic etching process. For example, the cover layer CL may be patterned by wet etching process using an etchant. Patterning of the cover layer CL may provide portions of the preliminary pixel defining layer, the preliminary spacer layer and portions of the third insulating layer IL3 which are exposed to outside the patterned cover layer CL.

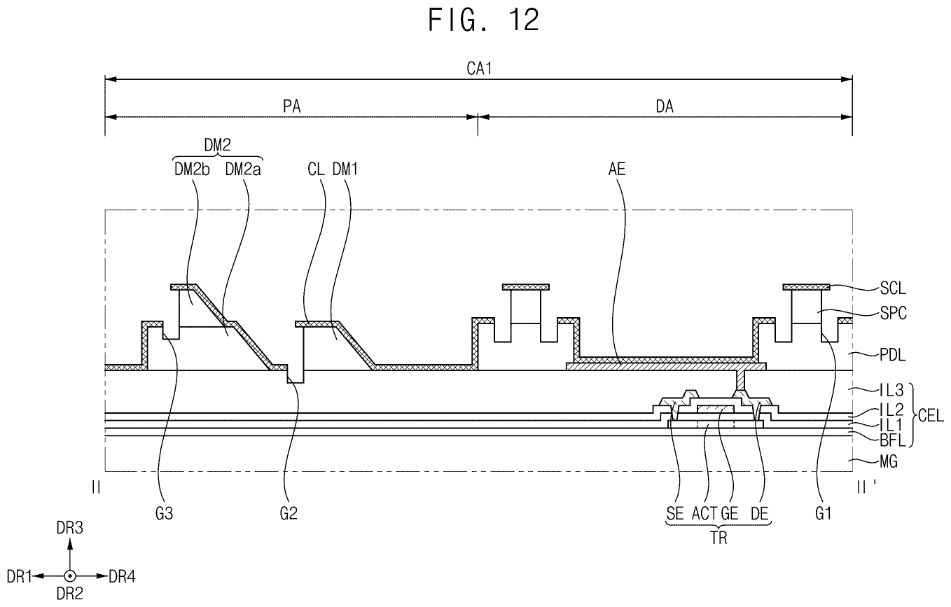

Referring to FIG. 12, after the cover layer CL is patterned, the first photoresist layer PR1 may be removed to expose disconnected portions of the cover layer CL, as well as expose portions of the preliminary pixel defining layer, portions of the preliminary spacer layer and portions of the third insulating layer IL3. Subsequently, a portion of the spacer SPC, a portion of the first dam DM1, and a portion of the second layer DM2b of the second dam DM2 may be removed so that the disconnected portions of the cover layer CL respectively protrude further from a side surface of each of the spacer SPC, the first dam DM1, and the second layer DM2b of the second dam DM2. Here, the method includes providing a spacer cover layer on the spacer SPC, together with providing a dam cover layer which is on the dam and protrudes further than a side surface of the dam only in a direction away from the display area DA.

In an embodiment, the portion of the spacer SPC, the portion of the first dam DM1, and the portion of the second layer DM2b of the second dam DM2 may be removed by isotropic ashing process (or isotropic etching process). For example, the portion of the spacer SPC, the portion of the first dam DM1, and the portion of the second layer DM2b of the second dam DM2 may be removed by isotropic ashing process using an etching gas. The etching gas may have a high etching rate for the spacer SPC, the first dam DM1, and the second layer DM2b of the second dam DM2 compared to an etching rate of the material of the cover layer CL. In an embodiment, the portion of the spacer SPC, the portion of the first dam DM1, and the portion of the second layer DM2b of the second dam DM2 may be removed together with the first photoresist layer PR1 in the process for removing the first photoresist layer PR1. The removal of the various portions of the aforementioned layers may provide an undercut structure at positions adjacent to dams and/or spacers.

In an embodiment, when the portion of the spacer SPC, the portion of the first dam DM1, and the portion of the second layer DM2b of the second dam DM2 is removed, a thickness portion of the pixel defining layer PDL adjacent to the spacer SPC may also be removed to define the first groove G1, a thickness portion of the third insulating layer IL3 adjacent to the first dam DM1 may be removed to define the second groove G2, and a thickness portion of the first layer DM2a adjacent to the second layer DM2b may be removed to define the third groove G3.

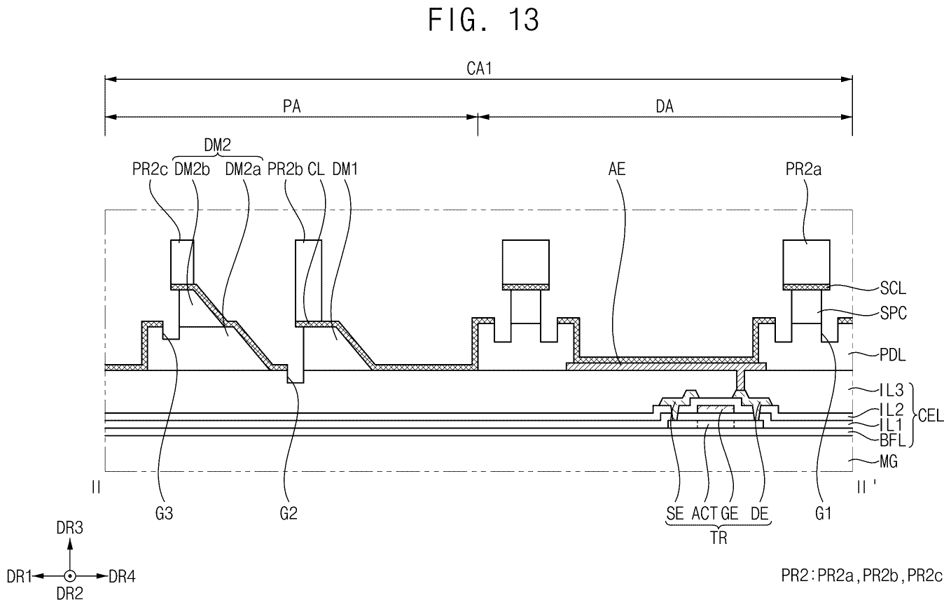

Referring to FIG. 13, a second photoresist layer PR2 may be formed on the patterned cover layer CL. In an embodiment, the second photoresist layer PR2 may be patterned to include a first pattern PR2a, a second pattern PR2b, and a third pattern PR2c spaced apart from each other in a direction along the circuit element layer CEL.

The first pattern PR2a may cover the spacer cover layer SCL on the spacer SPC. For example, the first pattern PR2a may have an island pattern shape in a plan view.

The second pattern PR2b may be disposed on the first dam DM1. The second pattern PR2b may cover an outer portion of the cover layer CL on the first dam DM1, and may not cover an inner portion of the cover layer CL closer to the display area DA. The second pattern PR2b may overlap at least a portion of the upper surface of the first dam DM1, and may not overlap the inner surface of the first dam DM1. For example, the second pattern PR2b may surround the display area DA in a plan view.

The third pattern PR2c may be disposed on the second dam DM2. The third pattern PR2c may cover an outer portion of the cover layer CL on the second layer DM2b of the second dam DM2, and may not cover an inner portion of the cover layer CL. The third pattern PR2c may overlap at least a portion of the upper surface of the second layer DM2b of the second dam DM2, and may not overlap the inner surface of the second layer DM2b of the second dam DM2. For example, the third pattern PR2c may surround the second pattern PR2b in a plan view. A remainder of the patterned cover layer CL except for the overlapped portions described above may be exposed to outside the second photoresist layer PR2.

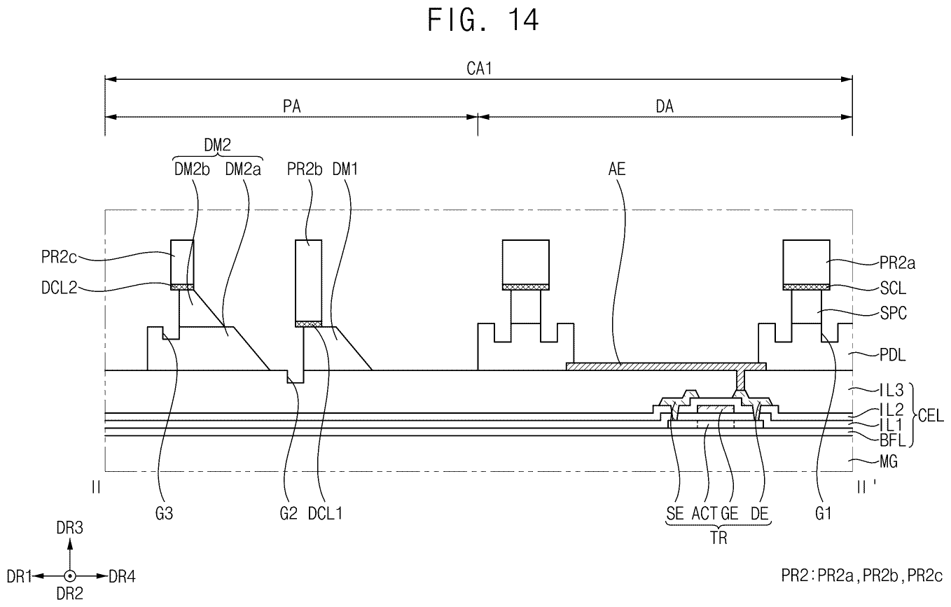

Referring to FIG. 14, the cover layer CL may be further patterned using the second photoresist layer PR2 as an etching mask. For example, the patterned cover layer CL of FIG. 13 may be further patterned by wet etching process using an etchant. As the patterned cover layer CL is further patterned, the first dam cover layer DCL1 which protrudes in only the outward direction (e.g., a direction opposite to the pixel defining layer PDL) may be formed on the first dam DM1, the second dam cover layer DCL2 which protrudes in only the outward direction (e.g., a direction opposite to the pixel defining layer PDL) and the spacer cover layer SCL may be formed on the second dam DM2. Here, remaining portions of the patterned cover layer CL in FIG. 13 may be removed, except for the first dam cover DCL1, the second dam cover DCL2 and the spacer cover layer SCL. That is, the first dam cover DCL1, the second dam cover DCL2 and the spacer cover layer SCL are in a same layer as each other.

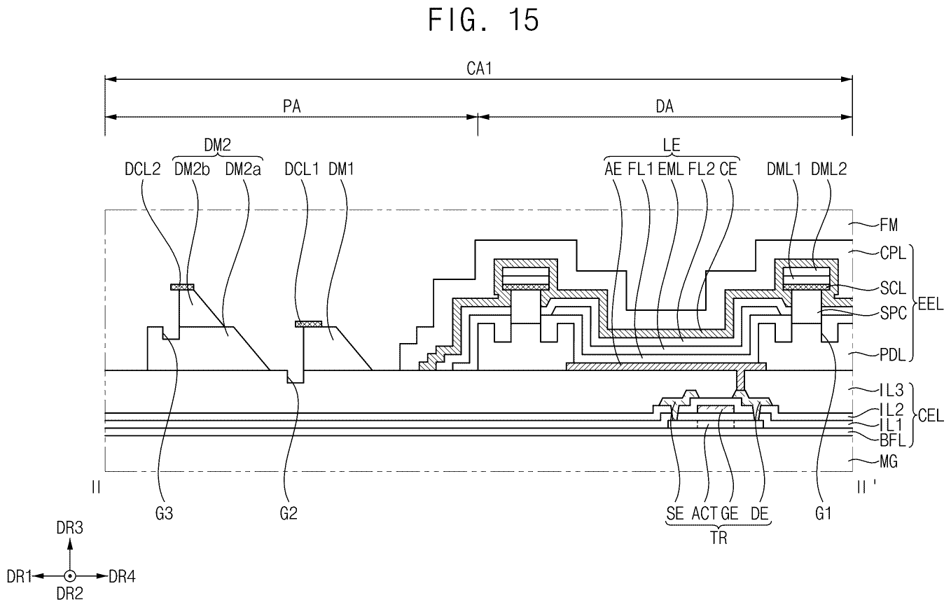

Referring to FIG. 15, the second photoresist layer PR2 may be removed. Then, respective material layers for providing the first functional layer FL1, the emission layer EML, the second functional layer FL2, the common electrode CE, and the capping layer CPL may be sequentially formed in the display area DA, thereby manufacturing the display substrate. On the mother substrate MG, a plurality of preliminary display substrates may be defined respectively corresponding to the first cell areas CA1 which are inclusive of a first substrate SUB1 as a portion of the mother substrate MG and the various layers thereon.

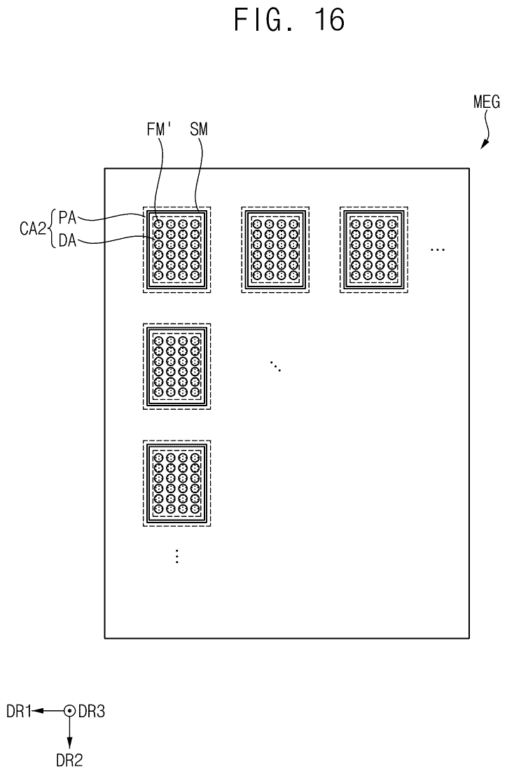

Referring to FIG. 16, a mother encapsulation substrate MEG including the same material as the second substrate SUB2 may be prepared. The mother encapsulation substrate MEG may be a substrate on which a plurality of cell areas are defined in order to obtain a plurality of display devices DD at once. The cell area defined on the mother encapsulation substrate MEG will be referred to as a second cell area CA2. A portion of the mother encapsulation substrate MEG corresponding to the second cell area CA2 may become the second substrate SUB2 through the cutting process described later. The second cell areas CA2 may respectively correspond to the first cell areas CA1.

As illustrated in FIG. 16, the sealant SM and a preliminary filler FM′ may be disposed on one surface of the mother encapsulation substrate MEG. The sealant SM may be applied on a peripheral area PA of each of the second cell areas CA2 of the mother encapsulation substrate MEG. The preliminary filler FM′ may be applied on a display area DA of each of the second cell areas CA2 of the mother encapsulation substrate MEG. For example, the preliminary filler FM′ may be applied using a jet dispenser.

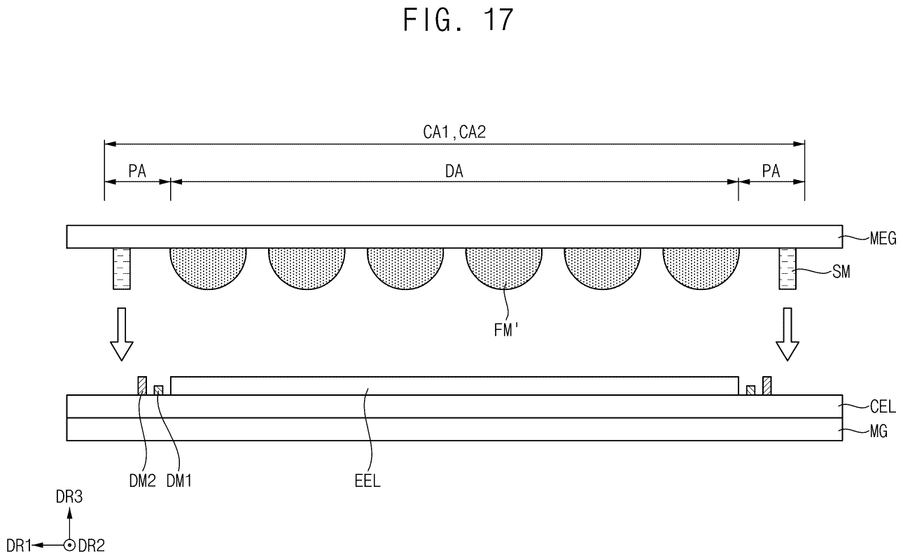

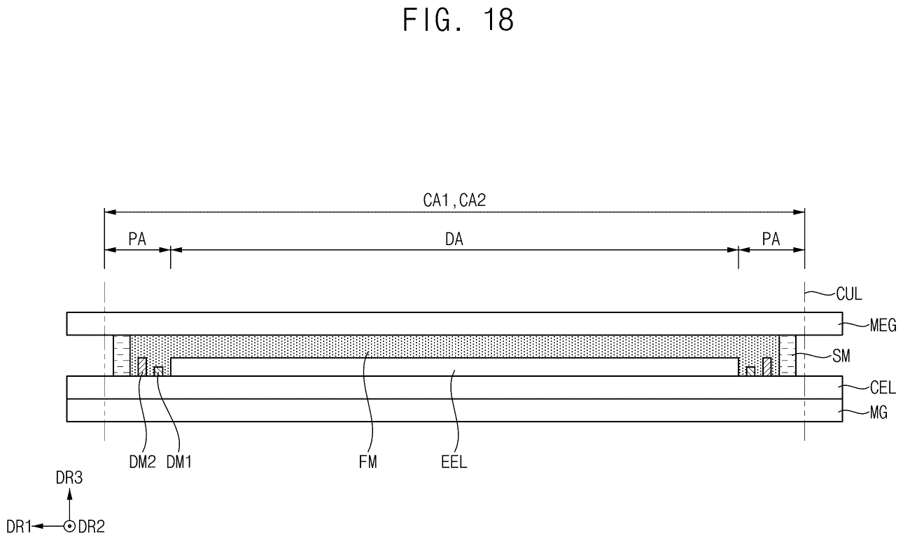

Referring to FIGS. 17 and 18, the mother substrate MG as a lower stacked structure and the mother encapsulation substrate MEG as an upper stacked structure may be bonded to each other. For example, the mother substrate MG may be disposed on or facing the mother encapsulation substrate MEG such that the one surface of the mother substrate MG face the one surface of the mother encapsulation substrate MEG. Here, the first cell areas CA1 may be oriented relative to the second cell area CA2, such as to be aligned with each other. Thereafter, a laser may be irradiated on the sealant SM to bond the mother substrate MG and the mother encapsulation substrate MEG to each other.

In the bonding process of the mother substrate MG and the mother encapsulation substrate MEG, a material of the preliminary filler FM′ applied on the display area DA may spread in the outward direction toward the sealant SM. According to embodiments, since the inner taper angle of each of the first dam DM1 and the second dam DM2 is relatively small, the first dam DM1 and the second dam DM2 may not interrupt the spreading of the filler FM in a direction from the display area DA toward the dams. Accordingly, a filler material may be spread to completely fill the inner space at the peripheral area PA, such that a non-filling defect of the filler FM may be prevented or reduced.

Next, the preliminary filler FM′ may be cured by heating to provide the filler FM. In the curing process of the preliminary filler FM′, air bubbles may be generated near the sealant SM due to shrinkage of the preliminary filler FM′. According to embodiments, since the outer taper angle of each of the first dam DM1 and the second dam DM2 is relatively large, and the first dam cover layer DCL1 and the second dam cover layer DCL2 each protruding in only the outward direction toward the sealant SM are respectively disposed on the first dam DM1 and the second dam DM2, it is possible to effectively block the air bubbles within the cured filler material from moving to the display area DA (e.g., in the inward direction). Accordingly, the lifting of the common electrode CE and/or the capping layer CPL due to the moved air bubbles may be prevented or reduced, and the resulting dark spot defect may be prevented or reduced. Accordingly, the display device DD with improved display quality and reliability may be manufactured.

Next, a bonded stacked structure including the bonded mother substrate MG and mother encapsulation substrate MEG having the cured sealing member and the cured filling member may be cut along a cutting line CUL, which is a boundary of each of the cell areas CA1 and CA2 relative to a remainder of the respective mother substrate. Here, a stacked structure corresponding to a display device DD may be separated from a remaining portion of the bonded stacked structure. The cutting line CUL corresponds to outer edges of both the first substrate SUB1 and the second substrate SUB2, that is, to an outer edge of the display device DD. Accordingly, the display device DD of FIGS. 1 to 5 may be obtained. That is, the method includes bonding a first portion of the mother substrate MG (e.g., the first substrate SUB1) having the cell areas and a corresponding second portion of the mother encapsulation substrate (e.g., the second substrate SUB2) having the filler and the sealant, to each other, to provide the display device DD including the first portion and the corresponding second portion.

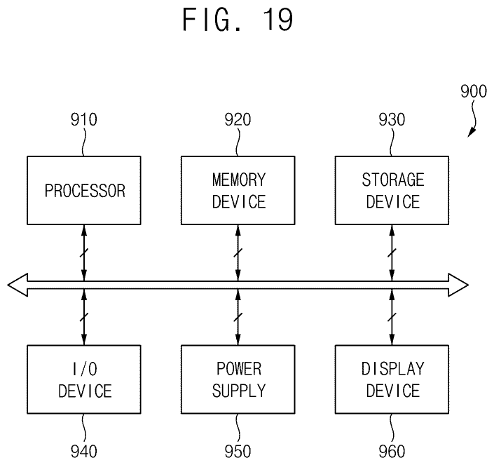

FIG. 19 is a block diagram illustrating an electronic device 900 according to an embodiment.

FIG. 19 is a block diagram illustrating an electronic device 900 according to an embodiment.

Referring to FIG. 19, in an embodiment, an electronic device 900 may include a processor 910, a memory device 920, a storage device 930, an input/output (“I/O”) device 940, a power supply 950, and a display device 960. Here, the display device 960 may correspond to the display device DD of FIG. 1. The electronic device 900 may further include a plurality of ports for communicating with a video card, a sound card, a memory card, a universal serial bus (“USB”) device, or the like. In an embodiment, the electronic device 900 may be implemented as a television. In an embodiment, the electronic device 900 may be implemented as a smart phone. However, embodiments are not limited thereto, in an embodiment, the electronic device 900 may be implemented as a cellular phone, a video phone, a smart pad, a smart watch, a tablet personal computer (“PC”), a car navigation system, a computer monitor, a laptop, a head disposed (e.g., mounted) display (“HMD”), or the like.

The processor 910 may perform various computing functions. In an embodiment, the processor 910 may be a microprocessor, a central processing unit (“CPU”), an application processor (“AP”), or the like. The processor 910 may be coupled to other components via an address bus, a control bus, a data bus, or the like. In an embodiment, the processor 910 may be coupled to an extended bus such as a peripheral component interconnection (“PCI”) bus.

The memory device 920 may store data for operations of the electronic device 900. In an embodiment, the memory device 920 may include at least one non-volatile memory device such as an erasable programmable read-only memory (“EPROM”) device, an electrically erasable programmable read-only memory (“EEPROM”) device, a flash memory device, a phase change random access memory (“PRAM”) device, a resistance random access memory (“RRAM”) device, a nano floating gate memory (“NFGM”) device, a polymer random access memory (“PoRAM”) device, a magnetic random access memory (“MRAM”) device, a ferroelectric random access memory (“FRAM”) device, or the like, and/or at least one volatile memory device such as a dynamic random access memory (“DRAM”) device, a static random access memory (“SRAM”) device, a mobile DRAM device, or the like.

In an embodiment, the storage device 930 may include a solid state drive (“SSD”) device, a hard disk drive (“HDD”) device, a CD-ROM device, or the like. In an embodiment, the I/O device 940 may include an input device such as a keyboard, a keypad, a mouse device, a touchpad, a touch-screen, or the like, and an output device such as a printer, a speaker, or the like.

The power supply 950 may provide power for operations of the electronic device 900. The display device 960 may be coupled to other components via the buses or other communication links. In an embodiment, the display device 960 may be included in the I/O device 940.

Although embodiments and implementations have been described herein, other embodiments and modifications will be apparent from this description. Accordingly, the invention is not limited to such embodiments, but rather to the broader scope of the appended claims and various obvious modifications and equivalent arrangements as would be apparent to a person of ordinary skill in the art.

What is claimed is:

1. A display device comprising:
a first substrate including a display area and a peripheral area which is outside the display area;
a circuit element layer including an insulating layer and a transistor in the display area, on the first substrate;
a light emitting element layer including a light emitting element which is in the display area and electrically connected to the transistor, on the circuit element layer;
a second substrate facing the light emitting element layer and defining a space therebetween;
a sealant which is in the peripheral area, between the first substrate and the second substrate, and bonds the first substrate and the second substrate to each other;
a filler which is inside of the sealant and fills the space between the first substrate and the second substrate; and
a dam which is in the peripheral area, on the circuit element layer, and between the light emitting element layer and the sealant in a direction along the first substrate, the dam including:
a first side surface which faces the sealant and a second side surface which faces the light emitting element layer in the direction along the first substrate, and
an angle between the first side surface and a lower surface of the dam which is greater than an angle between the second side surface and the lower surface of the dam.

2. The display device of claim 1, wherein in a plan view, the dam surrounds the light emitting element layer and the sealant surrounds the dam.

3. The display device of claim 1, further comprising:
a cover layer extended along an upper surface of the dam which is opposite to the lower surface of the dam, the cover layer protruding further than the first side surface in a direction toward the sealant.

4. The display device of claim 3, wherein the cover layer which protrudes further than the first side surface of the dam defines a cover first side surface which faces the sealant and is spaced apart from the first side surface in the direction toward the sealant.

5. The display device of claim 3, wherein the cover layer defines a cover second side surface which faces the light emitting element layer and is spaced apart from the second side surface in the direction toward the sealant.

6. The display device of claim 3, wherein the cover layer covers a portion of the upper surface of the dam which is adjacent to the sealant and exposes a remaining portion of the upper surface of the dam which is adjacent to the light emitting element layer.

7. The display device of claim 3, wherein the insulating layer of the circuit element layer is directly below the dam and defines a groove adjacent to the dam in the direction toward the sealant.

8. The display device of claim 7, wherein in a plan view, the groove surrounds the dam.

9. The display device of claim 1, further comprising:
the dam provided in plural including a first dam and a second dam which is further from the display area than the first dam,
wherein a thickness of the second dam is greater than a thickness of the first dam.

10. The display device of claim 9, wherein, in a plan view, the first dam surrounds the light emitting element layer, the second dam surrounds the first dam, and the sealant surrounds the second dam.

11. The display device of claim 9, wherein the second dam includes:
a first layer on the circuit element layer and having a thickness equal to the thickness of the first dam;
a second layer on the first layer; and
each of the first layer and the second layer having:
a first side sub-surface which faces the sealant and corresponds to the first side surface of the second dam, and
a second side sub-surface which faces the light emitting element layer and corresponding to the second side surface of the second dam.

12. The display device of claim 11, wherein within each of the first layer and the second layer, an angle between the first side sub-surface and a lower surface of the second dam is greater than an angle between the second side sub-surface and the lower surface of the second dam.

13. The display device of claim 12, further comprising:
cover layers respectively extended along an upper surface of each of the first dam and the second dam; and
the cover layers including a first cover layer and a second cover layer respectively protruding further than the first side surface of the first dam and the first side sub-surface of the the second dam, in a direction toward the sealant.

14. The display device of claim 13, wherein
the upper surface of the second dam is defined by the second layer; and
the second cover layer covers an entirety of the upper surface of the second dam which is defined by the second layer.

15. The display device of claim 13, wherein the first layer of the second dam defines a groove adjacent to the second layer of the second dam in the direction toward the sealant.

16. A display device comprising:
a first substrate including a display area and a peripheral area which is outside the display area;
a circuit element layer including an insulating layer and a transistor in the display area, on the first substrate;
a light emitting element layer including a light emitting element which is in the display area and electrically connected to the transistor, on the circuit element layer;
a second substrate facing the light emitting element layer and defining a space therebetween;
a sealant which is in the peripheral area, between the first substrate and the second substrate, and bonds the first substrate and the second substrate to each other;
a filler which is inside of the sealant and fills the space between the first substrate and the second substrate;
a dam which is in the peripheral area, on the circuit element layer, and between the light emitting element layer and the sealant; and
a cover layer on the dam and protruding further than the dam only in a direction toward the sealant.

17. The display device of claim 16, wherein
the dam has a first side surface facing the sealant and a second side surface facing the light emitting element layer; and
the cover layer includes:
a cover first side surface which faces the sealant and is spaced apart from the first side surface of the dam in the direction toward the sealant, and
a cover second side surface which faces the light emitting element layer and is spaced apart from the second side surface of the dam in the direction toward the sealant.

18. The display device of claim 17, wherein an angle between the first side surface of the dam and a lower surface of the dam is greater than an angle between the second side surface of the dam and the lower surface of the dam.

19. The display device of claim 16, further comprising:
the dam provided in plural including a first dam and a second dam which is further from the display area than the first dam, a thickness of the second dam being greater than a thickness of the first dam; and
cover layers respectively extended along an upper surface of each of the first dam and the second dam, the cover layers including a first cover layer and a second cover layer respectively protruding further than the first side surface of the first dam and the first side surface of the second dam, in the direction toward the sealant.

20. An electronic device comprising:
a display device configured to display an image;
a memory device configured to store data for the display device; and
a processor configured to perform computing functions for the display device,
wherein the display device includes:
a first substrate including a display area and a peripheral area which is outside the display area;
a circuit element layer including an insulating layer and a transistor in the display area, on the first substrate;
a light emitting element layer including a light emitting element which is in the display area and electrically connected to the transistor, on the circuit element layer;
a second substrate facing the light emitting element layer and defining a space therebetween;
a sealant which is in the peripheral area, between the first substrate and the second substrate, and bonds the first substrate and the second substrate to each other;
a filler which is inside of the sealant and fills the space between the first substrate and the second substrate; and
a dam which is in the peripheral area, on the circuit element layer, and between the light emitting element layer and the sealant in a direction along the first substrate, the dam including:
a first side surface which faces the sealant and a second side surface which faces the light emitting element layer in the direction along the first substrate, and
an angle between the first side surface and a lower surface of the dam which is greater than an angle between the second side surface and the lower surface of the dam.
